(19) United States
(12) Patent Application Publication
(10) Pub. No.: US 2024/0413290 A1
(43) Pub. Date: Dec. 12, 2024

(54) WIRING SUBSTRATE AND MANUFACTURING METHOD THEREFOR, LIGHT-EMITTING PANEL, AND DISPLAY DEVICE

(71) Applicants: Hefei BOE Ruisheng Technology Co., Ltd., Hefei,Anhui (CN); BOE Technology Group Co., Ltd., Beijing (CN)

(72) Inventors: Haifeng HU, Beijing (CN); Huan LIU, Beijing (CN); Xin ZHA, Beijing (CN); Ting ZENG, Beijing (CN)

(21) Appl. No.: 18/700,693

(22) PCT Filed: May 15, 2023
(86) PCT No.: PCT/CN2023/094329

§ 371 Date: Apr. 11, 2024

(30) Foreign Application Priority Data
Jun. 23, 2022 (CN) 202210724419.6

(51) Int. Cl. H01L 33/62; H01L 25/075; H01L 33/46

(52) U.S. Cl. CPC H01L 33/62; H01L 25/0753; H01L 33/46; H01L 2933/0025; H01L 2933/0066

(57) ABSTRACT

A wiring substrate, a manufacturing method thereof, a light-emitting panel, and a display device are disclosed. The wiring substrate includes: a base substrate (11); and a plurality of metal traces (50) and an organic insulating layer (13), which are located at one side of the base substrate. The metal traces (50) each comprise a first metal layer (141) and a second metal layer (151), which are stacked; the first metal layer (141) is located between the second metal layer (151) and the base substrate (11); an angle between a side wall of the second metal layer (151) and the base substrate (11) is greater than or equal to 90°; the area of a contact face between each of the metal traces (50) and the base substrate (11) is greater than or equal to the area of the surface of the second metal layer (151) opposite the first metal layer (141).

### CROSS-REFERENCE TO RELATED APPLICATION

The present application is a U.S. National Phase Entry of International Application No. PCT/CN2023/094329 having an international filing date of May 15, 2023, which claims priority to Chinese Patent Application No. 202210724419.6, filed to the CNIPA on Jun. 23, 2022 and entitled “Wiring Substrate and Manufacturing Method therefor, Light-Emitting Panel, and Display Device”. Contents of the above-identified applications should be interpreted as being incorporated into the present application by reference.

### TECHNICAL FIELD

Embodiments of the present disclosure relate to but are not limited to the technical field of display, and in particular relate to a wiring substrate and a manufacturing method thereof, a light-emitting panel, and a display device.

### BACKGROUND

Liquid Crystal Display (LCD) is the earliest popular and mature display technology, but with the improvement of panel technical performance requirements, LCD is difficult to meet the future needs. Organic Light Emitting Diode Display (OLED) is a new generation of display technology after LCD, which is already very mature. Mini LED (sub-millimeter light emitting diode chip) and Micro LED (micro light emitting diode chip) have excellent performance such as lower power consumption, faster response, longer life and better color saturation contrast. With the breakthrough of technology, Mini LED and Micro LED will become the next generation display technology after LCD and OLED.

Mini LED backlight can be used in TV, monitor, computer and other display products. The base substrates of Mini LED backlight products can be divided into glass base substrate and PCB base substrate. However, PCB base substrate itself has some problems such as poor heat dissipation and easy warping, while the glass base substrate has no such problems and has a greater prospect in the future.

### SUMMARY

The following is a summary of subject matters described herein in detail. This summary is not intended to limit the protection scope of the claims.

Embodiments of the present disclosure provide a wiring substrate, a manufacturing method thereof, a light-emitting panel and a display device.

As a first aspect of the embodiments of the present disclosure, an embodiment of the present disclosure provides a wiring substrate including:

a base substrate;

a plurality of metal traces located on a side of the base substrate, wherein a metal trace includes a first metal layer and a second metal layer which are stacked, the first metal layer is located between the second metal layer and the base substrate, an angle between a sidewall of the second metal layer and the base substrate is greater than or equal to 90°, and an area of a surface of the metal trace contacting with the base substrate is greater than or equal to an area of a surface of the second metal layer opposite to the first metal layer; and

an organic insulating layer disposed in the same layer as the metal traces, wherein a distance between a surface of the organic insulating layer away from the base substrate and the base substrate is greater than a distance between surfaces of the metal traces away from the base substrate and the base substrate, the organic insulating layer includes a plurality of first openings, the first openings expose a portion of the surfaces of the metal traces.

In some embodiments, an orthographic projection of the second metal layer on the base substrate is within a range of an orthographic projection of the first metal layer on the base substrate; or,

an orthographic projection of the first metal layer on the base substrate is within a range of an orthographic projection of the second metal layer on the base substrate, and a portion of the second metal layer is in direct contact with the base substrate in a plane parallel to the base substrate.

In some embodiments, a sidewall of the first metal layer is perpendicular to a surface of the base substrate.

In some embodiments, a reflective layer is also included that is disposed at least on a surface of a side of the organic insulating layer away from the base substrate.

In some embodiments, the material of the reflective layer is white ink.

In some embodiments, the reflective layer is also disposed on a sidewall of a first opening.

In some embodiments, a segment difference between a surface of a side of the reflective layer away from the base substrate and a surface of a side of the metal trace away from the base substrate is less than or equal to 10 μm.

In some embodiments, the reflective layer is also disposed on a surface of a side of the metal trace away from the base substrate, the reflective layer is provided with a second opening, an orthographic projection of the second opening on the base substrate is within an orthographic projection of the first opening on the base substrate, the second opening exposes a portion of the surface of the side of the metal trace away from the base substrate.

In some embodiments, the wiring substrate further includes an oxidization protective layer located in an exposed region of the metal trace, the oxidization protective layer is in direct contact with the metal trace, the material of the oxidization protective layer includes nickel and gold, and a thickness of the oxidization protective layer ranges from 4 μm to 5 μm.

In some embodiments, a ratio of a thickness of the first metal layer to a thickness of the organic insulating layer is less than or equal to 1/30.

As a second aspect of the embodiments of the present disclosure, an embodiment of the present disclosure provides a manufacturing method for a wiring substrate, including:

forming a photoresist layer on a side of a base substrate, patterning the photoresist layer to form a photoresist pattern region and a hollowed-out region, wherein the hollowed-out region has no photoresist, and an angle between a photoresist sidewall of the photoresist pattern region and the base substrate is less than or equal to 90°;

depositing a first metal thin film on a side of the base substrate facing the photoresist layer, wherein a ratio of a thickness of the first metal thin film to a thickness of the photoresist layer is less than or equal to 1/30, and the first metal thin film located in the hollowed-out region constitutes the first metal layer;

forming a second metal layer on at least a surface of the first metal layer facing away from the base substrate by an electroplating process, wherein a distance between a surface of the photoresist layer away from the base substrate and the base substrate is greater than a distance between a surface of the second metal layer away from the base substrate and the base substrate; and

removing the first metal thin film on the surface of the photoresist layer away from the base substrate to obtain a wiring substrate, wherein the photoresist in the photoresist pattern region constitutes an organic insulating layer, and a metal trace includes the first metal layer and the second metal layer in the hollowed-out region.

In some embodiments, the method further includes:

forming a reflective layer on a side of the organic insulating layer and the metal trace away from the base substrate by a screen printing process, wherein the reflective layer is provided with a second opening, an orthographic projection of the second opening on the base substrate is within an orthographic projection of the hollowed-out region on the base substrate, and the second opening exposes a portion of a surface of the side of the metal trace away from the base substrate.

In some embodiments, the method further includes performing electroless nickel immersion gold on the exposed surface of the metal trace.

As a third aspect of the embodiments of the present disclosure, an embodiment of the present disclosure provides a light-emitting panel, which includes a wiring substrate in any of embodiments of the present disclosure, and also includes a plurality of light emitting diode chips, and the plurality of light emitting diode chips are correspondingly connected with the metal traces.

As a fourth aspect of the embodiments of the present disclosure, an embodiment of the present disclosure provides a display device including a light-emitting panel in the embodiments of the present disclosure.

The above summary is for the purpose of the specification only and is not intended to limit in any manner. Further aspects, embodiments and features of the present disclosure will be readily understood by referring to the accompanying drawings and the detailed description below in addition to the illustrative aspects, embodiments and features described above.

Other aspects may be comprehended after the drawings and the detailed descriptions are read and understood.

### BRIEF DESCRIPTION OF DRAWINGS

In the accompanying drawings, unless otherwise specified, same reference numerals throughout a plurality of drawings indicate same or similar components or elements. These drawings may not be drawn to scale. It should be understood that these drawings depict only some implementations according to the present disclosure and should not be considered as limiting the scope of the present disclosure.

FIG. 1 is a schematic diagram of a manufacturing process of a wiring substrate;

FIG. 2 is a schematic diagram of a partial structure of a wiring substrate according to an embodiment of the present disclosure;

FIG. 3 is an enlarged schematic diagram of Part M in FIG. 2;

FIG. 4 is a schematic diagram of a cross-sectional structure taken along A-A of FIG. 2 according to an embodiment of the present disclosure;

FIG. 5 is a schematic diagram of a cross-sectional structure taken along A-A of FIG. 2 according to another embodiment of the present disclosure;

FIG. 6A is a schematic diagram of a wiring substrate after forming a photoresist layer according to an embodiment of the present disclosure;

FIG. 6B is a schematic diagram of a wiring substrate after forming a first metal thin film according to an embodiment of the present disclosure;

FIG. 6C is a schematic diagram of a wiring substrate after forming a second metal layer according to an embodiment of the present disclosure;

FIG. 6D is a schematic diagram of a wiring substrate after removing a first metal thin film on an upper surface of the photoresist layer according to an embodiment of the present disclosure;

FIG. 6E is a schematic diagram of a wiring substrate after forming a reflective layer according to an embodiment of the present disclosure; and

FIG. 7 is a schematic diagram of a wiring substrate after removing a first metal thin film on an upper surface of a photoresist layer according to another embodiment of the present disclosure.

### DETAILED DESCRIPTION

Hereinafter, only some exemplary embodiments are briefly described. As will be recognized by those skilled in the art, the described embodiments may be modified in a variety of different ways without departing from the spirit or scope of the present disclosure, and the different embodiments may be arbitrarily combined if there is no conflict. Therefore, the drawings and description are considered to be exemplary in nature and not restrictive.

Herein, the thickness of the film layer is the size of the film layer in the direction perpendicular to its bearing surface.

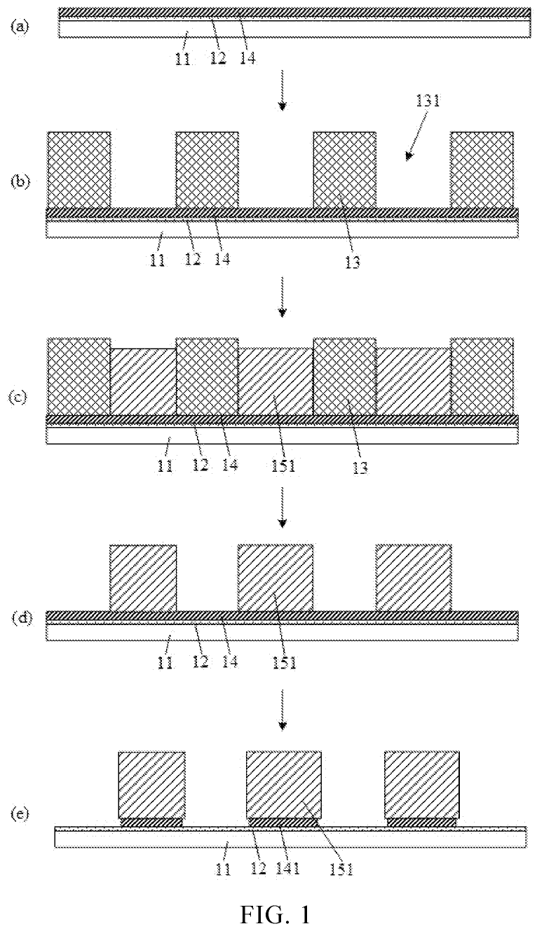

FIG. 1 is a schematic diagram of a manufacturing process of a wiring substrate. As shown in FIG. 1, a buffer layer 12 is deposited on a base substrate 11, a first metal thin film 14 is deposited on the buffer layer 12. A photoresist is coated on a side of the first metal thin film 14 facing away from the base substrate 11, the photoresist is exposed and developed to form a photoresist layer 13 including a photoresist pattern region and a hollowed-out region 131. A second metal layer 151 is grown on the first metal thin film 14 in the hollowed-out region 131 by an electroplating process. The photoresist layer 13 is peeled off, and the first metal thin film 14 positioned outside the second metal layer 151 is etched to form a first metal layer 141, and the first metal layer 141 is positioned between the second metal layer 151 and the base substrate 11. As shown in FIG. 1, a metal trace includes the first metal layer 141 and the second metal layer 151 which are stacked. As shown in FIG. 1 (e), when the first metal thin film 14 is etched, due to the etching process, the formed first metal layer 141 retracts inward relative to the second metal layer 151, so that a contact area between the first metal layer 141 and the buffer layer 12 is reduced, and the contact area between the metal trace and the buffer layer 12 is smaller than the area of the bottom surface of the second metal layer 151, thus reducing the adhesion between the first metal layer 141 and the base substrate 11, and there is a risk that the first metal layer 141 will fall off.

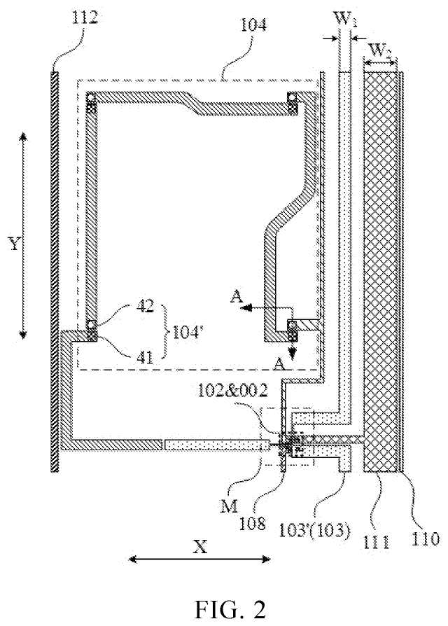

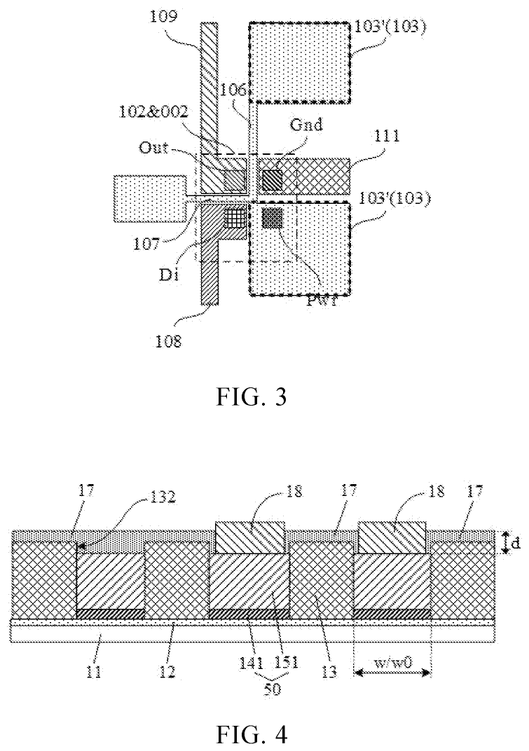

FIG. 2 is a schematic diagram of a partial structure of a wiring substrate according to an embodiment of the present disclosure; FIG. 3 is an enlarged schematic diagram of Part M in FIG. 2; FIG. 4 is a schematic diagram of a cross-sectional structure taken along A-A of FIG. 2 in an embodiment; and FIG. 5 is a schematic diagram of a cross-sectional structure taken along A-A of FIG. 2 in another embodiment. In one implementation, as shown in FIG. 2 to FIG. 5, the wiring substrate includes a base substrate 11, an organic insulating layer 13 and a plurality of metal traces 50. The plurality of metal traces 50 are located on a side of the base substrate 11, and a metal trace 50 includes a first metal layer 141 and a second metal layer 151 that are stacked, the first metal layer 141 is located between the base substrate 11 and the second metal layer 151. In an example, an angle between a sidewall of the second metal layer 151 and the base substrate 11 is greater than or equal to 90°. The area of the surface of the metal trace 50 contacting with the base substrate 11 is greater than or equal to the area of the surface of the second metal layer 151 opposite to the first metal layer 141. For example, in FIG. 4 and FIG. 5, a width of the surface of the second metal layer 151 opposite to the first metal layer 141 is w, and a width w0 of the surface of the metal trace 50 in contact with the base substrate 11 is greater than or equal to w, so that the area of the surface of the metal trace 50 contacting with the base substrate 11 is greater than or equal to the area of the surface of the second metal layer 151 opposite to the first metal layer 141.

The organic insulating layer 13 and the metal traces 50 are disposed in the same layer. A distance between a surface of the organic insulating layer 13 away from the base substrate 11 and the base substrate 11 is greater than a distance between a surface of the metal trace 50 away from the base substrate 11 and the base substrate 11. The organic insulating layer includes a plurality of first openings 132 that expose a portion of the surfaces of the metal traces 50. In an example, the plurality of first openings 132 may correspond one-to-one with the plurality of metal traces, and the first openings 132 expose a portion of the surfaces of the metal traces 50 away from the base substrate 11, as shown in FIG. 4 and FIG. 5. The sidewalls of the first openings 132 are shown in FIG. 4 and FIG. 5.

Herein, the organic insulating layer 13 is disposed in the same layer as the metal traces 50, which can be understood that a surface of the organic insulating layer 13 facing the base substrate 11 and surfaces of the metal traces 50 facing the base substrate 11 are in the same horizontal plane, which can also be understood that a lower surface of the organic insulating layer 13 and lower surfaces of the metal traces 50 are in the same horizontal plane. In the embodiments of FIG. 4 and FIG. 5, both the organic insulating layer 13 and the metal traces 50 are located on an upper surface of the base substrate 11 or the buffer layer 12. The organic insulating layer 13 is disposed in the same layer as the metal traces 50, which can also be understood that both the organic insulating layer 13 and the metal traces 50 are located on the upper surface of the base substrate 11 or the buffer layer 12, and the organic insulating layer 13 is filled between the metal traces 50, or the organic insulating layer 13 is filled in the regions outside the metal traces 50.

In the wiring substrate according to an embodiment of the present disclosure, as shown in FIG. 4 and FIG. 5, the first metal layer 141 is positioned between the second metal layer 151 and the base substrate 11, an angle between a sidewall of the second metal layer 151 and the base substrate 11 is greater than or equal to 90°, and an area of a surface of the metal trace 50 contacting with the base substrate 11 is greater than or equal to an area of a surface of the second metal layer 151 opposite to the first metal layer 141. With such a structure, there is no longer a problem that the surface of the metal trace 50 contacting with the base substrate 11 retracts inward, the contact area between the metal trace and the base substrate is increased, the adhesion between the metal trace 50 and the base substrate 11 is improved, and the risk of the metal trace 50 falling off is reduced. In addition, the organic insulating layer 13 can protect the sidewalls of the metal traces 50 from water-oxygen corrosion caused by the sidewalls of the metal traces 50 contacting with water-oxygen.

In one implementation, as shown in FIG. 4, an angle between a sidewall of the second metal layer 151 and the base substrate 11 is equal to 90°, and an orthographic projection of the second metal layer 151 on the base substrate 11 is within a range of an orthographic projection of the first metal layer 141 on the base substrate. Thus, the width w0 of the surface of the metal trace 50 in contact with the base substrate 11 is equal to the width w of the surface of the second metal layer 151 opposite to the first metal layer 141, that is, the area of the surface of the metal trace 50 in contact with the base substrate 11 is equal to the area of the surface of the second metal layer 151 opposite to the first metal layer 141.

In one implementation, as shown in FIG. 5, the angle between the sidewall of the second metal layer 151 and the base substrate 11 is greater than 90°, and the second metal layer 151 wraps the first metal layer 141. In an example, the orthographic projection of the first metal layer 141 on the base substrate 11 is within the range of the orthographic projection of the second metal layer 151 on the base substrate 11, and a portion of the second metal layer 151 outside the first metal layer 141 is in direct contact with the base substrate 11 on a plane parallel to the base substrate 11. Thus, the width w0 of the surface of the metal trace 50 in contact with the base substrate 11 is greater than the width w of the surface of the second metal layer 151 opposite to the first metal layer 141, and further, the area of the surface of the metal trace 50 in contact with the base substrate 11 is larger than the area of the surface of the second metal layer 151 opposite to the first metal layer 141.

In an example, the sidewall of the first metal layer 141 is perpendicular to the surface of the base substrate 11, that is, the sidewall of the first metal layer 141 is perpendicular to the surface of the base substrate 11 within an allowable error range, or an angle between the sidewall of the first metal layer 141 and the surface of the base substrate 11 is greater than or equal to 90° within an allowable error range.

In an example, the material of the base substrate 11 may include glass, for example, the material of the base substrate is glass.

In one implementation, the material of the organic insulating layer 13 may include an organic material, for example, the material of the organic insulating layer 13 may be a resin material, such as one of polyimide, photoresist, and the like.

In one implementation, the material of the first metal layer 141 includes copper, for example, the material of the first metal layer 141 is copper metal. The material of the second metal layer 151 includes copper, for example, the material of the second metal layer 151 includes copper metal. Copper metal has the characteristics of low resistivity and good conductivity. A copper metal layer can be prepared by any of sputtering, deposition, electroplating, electroforming, coating, printing and the like.

In one implementation, the first opening 132 may extend along an extension direction of the metal trace 50. In an example, as shown in FIG. 4 and FIG. 5, the sidewall of the first opening 132 and the sidewall of the metal trace 50 may be mutually parallel or coincident.

In one implementation, a ratio of a thickness of the first metal layer to a thickness of the second metal layer ranges from 1:20 to 1:25. In an example, the thickness of the first metal layer 141 ranges from 0.2 μm to 0.4 μm (including endpoint values). For example, the thickness of the first metal layer 141 which is obtained by a sputtering process may be 0.3 μm. The thickness of the second metal layer 151 ranges from 5 μm to 8 μm (including endpoint values), for example, the thickness of the second metal layer 151 may be 6.5 μm. The second metal layer 151 is obtained by an electroplating process, so that the thickness of the second metal layer 151 can reach 5 μm to 8 μm, thus reducing the resistance of the metal trace.

In one implementation, the thickness of the organic insulating layer 13 ranges from 10 μm to 16 μm (including endpoint values). For example, the thickness of the organic insulating layer 13 may be 13 μm.

In one implementation, as shown in FIG. 4 and FIG. 5, the wiring substrate may further include a reflective layer 17 disposed at least on a surface of the organic insulating layer 13 away from the base substrate 11. The reflective layer 17 can reflect the light emitted to the base substrate 11 toward a light emitting side, thereby improving the utilization rate of light energy. The reflective layer 17 can also protect the organic insulating layer 13, prevent the organic insulating layer 13 from contacting with water vapor, prevent the organic insulating layer 13 from bubbling caused by absorbing water in long-term contact with the environment, and prevent water-oxygen corrosion of the metal traces.

In one implementation, the material of the reflective layer 17 may be white ink. The white ink can not only play a reflective role, but also prevent water vapor from entering the organic insulating layer 13, thus playing a protective role on the organic insulating layer 13. In an example, the material of the reflective layer 17 may be white ink having a reflective function.

In one implementation, as shown in FIG. 4 and FIG. 5, the reflective layer 17 is also disposed on the sidewall of the first opening 132, so that the reflective layer 17 can completely cover the exposed surface of the organic insulating layer 13, prevent the organic insulating layer 13 from bubbling caused by absorbing water vapor, and better prevent water-oxygen corrosion of the metal traces.

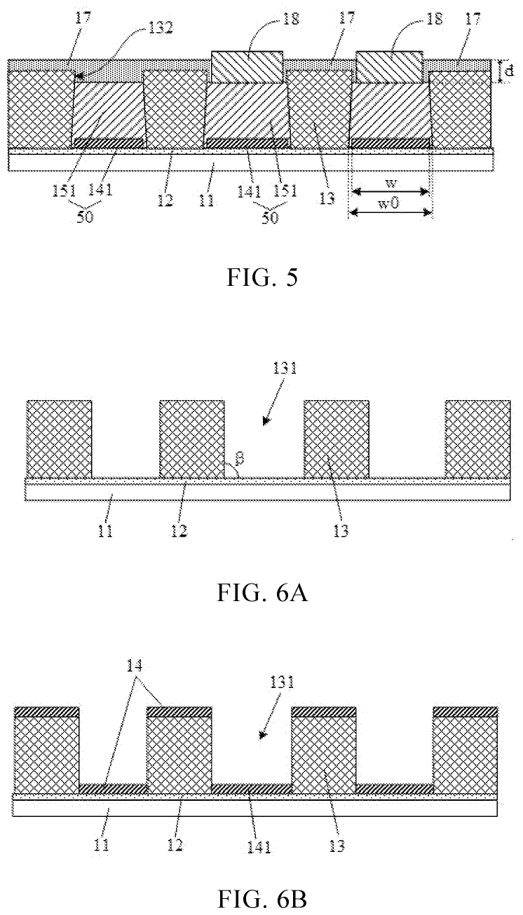

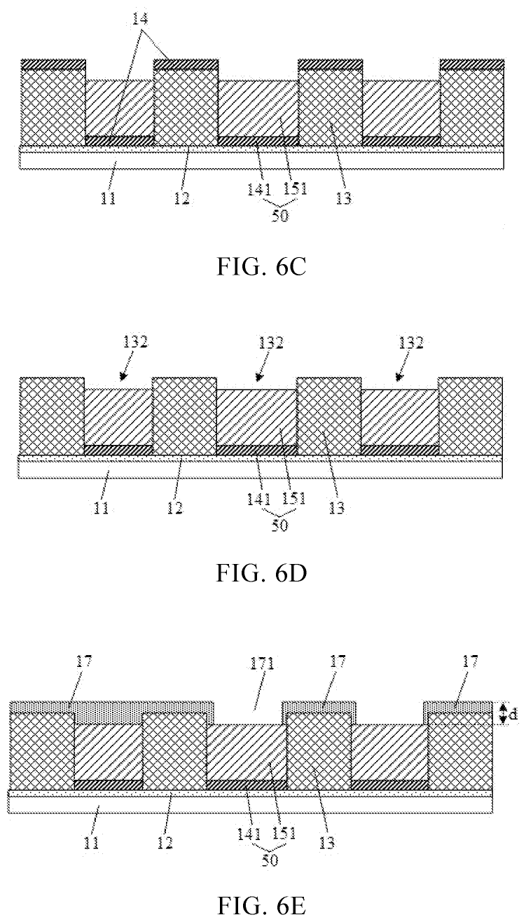

In one implementation, as shown in FIG. 4 and FIG. 5, the reflective layer 17 is also disposed on a surface of the metal trace 50 away from the base substrate 11, so that the metal trace 50 can be prevented from being eroded by water and oxygen. In an example, the reflective layer 17 is provided with a second opening 171 (see FIG. 6E), an orthographic projection of the second opening 171 on the base substrate 11 is within an orthographic projection of the first opening 131 on the base substrate 11, and the second opening 171 exposes a portion of the surface of the metal trace 50 away from the base substrate 11. The exposed surface of the metal trace 50 may be used to connect with an electronic component such as a light emitting diode chip, or a micro drive chip, a circuit board, or the like.

In one implementation, as shown in FIG. 4 and FIG. 5, the wiring substrate may also include an oxidization protective layer 18 located in exposed regions of the metal traces 50 that are not covered by the organic insulating layer 13, the oxidization protective layer 18 is in direct contact with the metal traces 50, and the oxidization protective layer 18 covers the exposed regions of the metal traces 50. The oxidization protective layer 18 may prevent the exposed regions of the metal traces 50 from being oxidized.

In an example, the material of the oxidization protective layer 18 includes nickel and gold, and the thickness of the oxidization protective layer 18 ranges from 4 μm to 5 μm (including endpoint values). The light emitting diode chip or micro drive chip is connected to the metal trace 50 through the oxidization protective layer 18 by a die bonding process. Such an oxidization protective layer 18 can not only better prevent the metal traces 50 from being oxidized and eroded, but also improve the die bonding yield.

In one implementation, as shown in FIG. 4 and FIG. 5, a segment difference d between the surface of the reflective layer 17 away from the base substrate 11 and the surface of the metal trace 50 away from the base substrate 11 is less than or equal to 10 μm. Such arrangement is beneficial to the subsequent die bonding or binding process and improves the yield.

In an example, the light emitting diode chip may be a Mini Light Emitting Diode (Mini LED) chip, or may be a Micro Light Emitting Diode (Micro LED) chip.

In an example, a plurality of regions of the metal traces 50 covered by the oxidization protective layer 18 and the oxidization protective layer 18 above the corresponding regions may constitute pads. For example, after a reflow soldering process, each pad and one pin of the electronic component may be electrically connected by a soldering metal, which may include tin, and the electronic component may include at least one of a light emitting diode chip, a micro drive chip, a sensor chip, and the like.

In one implementation, as shown in FIG. 2 and FIG. 3, the wiring substrate may include a first pad group 102, a second pad group 104, and the metal traces include a power supply signal line 103. The first pad group 102 includes a power supply pad Pwr and an output pad Out. Optionally, the first pad group 102 is coupled to a micro drive chip 002. The power supply signal line 103 is coupled to the power supply pad Pwr. The second pad group 104 is coupled to a light emitting diode chip. The second pad group 104 includes a plurality of sub-pad groups 104′ electrically connected to each other, each sub-pad group 104′ at least includes a first sub-pad 41 and a second sub-pad 42, the first sub-pad 41 of at least one sub-pad group 104′ of each second pad group 104 is coupled to the power supply signal line 103, and the second sub-pad 42 of at least one sub-pad group 104′ of each second pad group 104 is coupled to the output pad Out in one first pad group 102. The first pad group 102 and the second pad group 104 are connected to the same power supply signal line 103.

As shown in FIG. 2 and FIG. 3, the metal traces may also include a first connection lead 106, one power supply signal line 103 includes a plurality of sub-segments 103′, and two adjacent sub-segments 103′ may be connected to each other through one first connection lead 106. A line width of the power supply signal line 103 is 0.35 mm, and a line width W1 of the sub-segment 103′ may be greater than 0.35 mm and less than or equal to 1.85 mm.

As shown in FIG. 2 and FIG. 3, the metal traces may also include a second connection lead 107. Optionally, the second connection lead 107 is integrated with the first connection lead 106.

In an example, as shown in FIG. 3, the first pad group 102 also includes an address pad Di and a ground pad Gnd. The address pad Di and the power supply pad Pwr belonging to the same first pad group 102 are arranged at intervals in the first direction X. The address pad Di and the output pad Out belonging to the same first pad group 102 are arranged at intervals in the second direction Y. The second direction Y is perpendicular to the first direction X. The ground pad Gnd and the power supply pad Pwr are arranged at intervals in the second direction Y, and the ground pad Gnd and the output pad Out are arranged at intervals in the first direction X. In an example, the output pad Out is located in the upper left corner of the first pad group 102, the address pad Di is located in the lower left corner of the first pad group 102, the ground pad Gnd is located in the upper right corner of the first pad group 102, and the power supply pad Pwr is located in the lower right corner of the first pad group 102.

Optionally, each first pad group 102 may be coupled to one micro drive chip 002, and each second pad group 104 is coupled to a plurality of light emitting diode chips. In some embodiments, the address pad Di may receive an address signal for use in gating the micro drive chip 002 with the corresponding address. The power supply pad Pwr can provide a first working voltage and communication data for the micro drive chip 002, the communication data can be used to control the luminance of the corresponding light emitting element. The output pad Out can respectively output a relay signal and a drive signal in different time periods. Optionally, the relay signal is an address signal supplied to the address pad Di in the first pad group 102 of next stage, and the drive signal is a drive current for driving the light emitting element coupled with the first pad group 102 where the output pad Out is located to emit light. The ground pad Gnd receives a common voltage signal.

In some embodiments, as shown in FIG. 2, the metal traces further include an address signal line 108, and one address signal line 108 may be coupled to the address pad Di of the first pad group 102.

As shown in FIG. 3, the metal traces further include a cascade line 109. A plurality of first pad groups 102 are provided, and the cascade line 109 is configured to connect an output pad Out of a first pad group 102 of the nth stage with an address pad Di of a first pad group 102 of the (n+1) th stage belonging to the same pad region, where n is a positive integer, so as to supply a relay signal output by the output pad Out of the first pad group 102 of the nth stage to the address pad Di of the first pad group 102 of the (n+1) th stage through the cascade line 109.

As shown in FIG. 2, the metal traces further include a feedback signal line 110, and one feedback signal line 110 is coupled to the output pad Out of the first pad group 102 of the last stage in the first pad groups 102 of the plurality of stages.

As shown in FIG. 2 and FIG. 3, the metal traces may also include a common voltage signal line 111, and one common voltage signal line 111 is coupled to the ground pads Gnd of all of the first pad groups 102 in one pad region. A line width W2 of the common voltage signal line 111 may be greater than 1 mm and less than or equal to 2.5 mm.

In FIG. 2 and FIG. 3, different metal traces, such as the power supply signal line 103, the first connection lead 106, the second connection lead 107, the address signal line 108, the cascade line 109, the feedback signal line 110, and the common voltage signal line 111, are represented with different fillings. In an example, the power supply signal line 103, the first connection lead 106, the second connection lead 107, the address signal line 108, the cascade line 109, the feedback signal line 110, and the common voltage signal line 111 may be simultaneously formed by using the same process.

In an example, as shown in FIG. 2, the metal traces also include an Electro-Static Discharge (ESD) trace 112 located on the periphery and configured for anti-static protection of the wiring substrate. Optionally, the ESD trace 112 is located at the periphery of any signal line, any connection line, any trace, the first pad group 102 and the second pad group 104, and forms a ring-shaped structure.

An embodiment of the present disclosure also provides a light-emitting panel, which can include a wiring substrate in any of embodiments of the present disclosure, and also includes a light emitting diode chip, and the light emitting diode chip is connected with corresponding metal trace.

An embodiment of the present disclosure also provides a display device including a light-emitting panel in any of embodiments of the present disclosure.

The light-emitting panel in the embodiment of the present disclosure can be assembled in the display device as a display panel or as a light source. The display device can be any of products or components with display function, such as electronic paper, mobile phone, tablet computer, television, display, notebook computer, digital photo frame, navigator, wearable display apparatus, etc.

The light-emitting panel in the embodiment of the present disclosure can also be used as a light emitting source in a lighting product.

An embodiment of the present disclosure also provides a manufacturing method for the wiring substrate, the manufacturing method for the wiring substrate may include:

forming a photoresist layer on a side of a base substrate, patterning the photoresist layer to form a photoresist pattern region and a hollowed-out region, wherein no photoresist is in the hollowed-out region, and an angle between a photoresist sidewall of the photoresist pattern region and the base substrate is less than or equal to 90°;

depositing a first metal thin film on a side of the base substrate facing the photoresist layer, wherein a ratio of a thickness of the first metal thin film to a thickness of the photoresist layer is less than or equal to 1/30, and the first metal thin film located in the hollowed-out region constitutes the first metal layer;

forming a second metal layer on at least a surface of the first metal layer facing away from the base substrate by an electroplating process, wherein a distance between a surface of the photoresist layer away from the base substrate and the base substrate is greater than a distance between a surface of the second metal layer away from the base substrate and the base substrate;

removing the first metal thin film on the surface of the photoresist layer away from the base substrate to obtain a wiring substrate, wherein the photoresist in the photoresist pattern region constitutes an organic insulating layer, and a metal trace includes the first metal layer and the second metal layer in the hollowed-out region.

In one implementation, the manufacturing method for a wiring substrate further includes: forming a reflective layer on a side of the organic insulating layer and the metal traces away from the base substrate by using a screen printing process, wherein the reflective layer is provided with a second opening, an orthographic projection of the second opening on the base substrate is within an orthographic projection of the hollowed-out region on the base substrate, and the second opening exposes a portion of the surface of a side of the metal trace away from the base substrate.

In one implementation, the manufacturing method for a wiring substrate further includes: performing ENIG (Electroless Nickel Immersion Gold) on the exposed surface of the metal trace.

The technical solution of the embodiments of the present disclosure is further described below by means of a process for manufacturing a wiring substrate according to an embodiment of the present disclosure. It may be understood that, for “patterning” mentioned in the present disclosure, when a patterned material is an inorganic material or metal, the “patterning” includes a process such as photoresist coating, mask exposure, development, etching, and photoresist stripping; and when the patterned material is an organic material, the “patterning” includes a process such as mask exposure and development. Evaporation, deposition, coating, and spreading, etc., mentioned in the present disclosure are all mature manufacturing processes in the related art.

The manufacturing method of a wiring substrate provided by the embodiment of the present disclosure is described below with reference to the drawings.

A photoresist layer 13 is formed on a side of the base substrate 11, and the photoresist layer 13 is patterned to form a photoresist pattern region and a plurality of hollowed-out regions 131. FIG. 6A is a schematic diagram of a wiring substrate after forming a photoresist layer according to an embodiment of the present disclosure. As shown in FIG. 6A, a buffer layer 12 may be deposited on a side of the base substrate 11 (optionally), a photoresist may be coated on a side of the buffer layer 12 facing away from the base substrate 11, and a photoresist layer 13 may be formed after exposure and development of the photoresist by using a mask. The photoresist layer 13 includes a photoresist pattern region and a plurality of hollowed-out regions 131. In an example, as shown in FIG. 6A, an angle β between a photoresist sidewall of the photoresist pattern region and the base substrate 11 may be less than or equal to 90°. That is, the cross-sectional shape of the photoresist of the photoresist pattern region is rectangular or inverted trapezoid. A thickness of the photoresist layer 13 may range from 10 μm to 16 μm (including endpoint values), for example, the thickness of the photoresist layer 13 may be 13 μm. In an example, the buffer layer 12 may be made of any one or more of silicon oxide (SiOx), silicon nitride (SiNx), and silicon oxynitride (SiON), and may be single-layer, multilayer, or composite layer. The buffer layer can improve the water and oxygen resistance of the base substrate 11.

A first metal thin film 14 is deposited on a side of the base substrate 11 facing the photoresist layer 13. In an example, a ratio of a thickness of the first metal thin film 14 to the thickness of the photoresist layer 13 is less than or equal to 1/30. Since the thickness of the first metal thin film 14 is much less than the thickness of the photoresist layer 13, the first metal thin film 14 located in the hollowed-out region 131 and the first metal thin film 14 located on the surface of the photoresist layer 13 facing away from the base substrate 11 are not connected to each other, and the first metal thin film 14 located in the hollowed-out region 131 constitutes a first metal layer 141, as shown in FIG. 6B. FIG. 6B is a schematic diagram of a wiring substrate after forming a first metal thin film according to an embodiment of the present disclosure. In an example, the thickness of the first metal thin film 14 may be from 0.2 μm to 0.4 μm, so that the thickness difference between the first metal thin film 14 and the photoresist layer 13 is relatively large. In this way, adhesion between the first metal thin film 14 in the hollowed-out region 131 and the first metal thin film 14 on the upper surface of the photoresist layer 13 can be avoided. In addition, since the angle β is less than or equal to 90°, the adhesion between the first metal thin film 14 in the hollowed-out region 131 and the first metal thin film 14 on the upper surface of the photoresist layer 13 can be avoided when the first metal thin film 14 is formed by the deposition process. In an example, the first metal layer may be referred to as a seed layer.

A second metal layer 151 is formed on at least a surface of the first metal layer 141 facing away from the base substrate 11 by an electroplating process, as shown in FIG. 6C. FIG. 6C is a schematic diagram of a wiring substrate after forming a second metal layer according to an embodiment of the present disclosure. In an example, the base substrate 11 on which the first metal thin film 14 is formed may be put into an electroplating solution, and the first metal layer 141 located in at least one hollowed-out region 131 may be electrified, so that the second metal layer 151 may be grown on the surface of the electrified first metal layer 141. Since the angle β is equal to 90° in this embodiment, after the first metal layer 141 is formed by the deposition process, the upper surface of the first metal layer 141 is exposed and the side surface of the first metal layer 141 is in contact with the photoresist. Therefore, the second metal layer 151 is formed on the upper surface of the first metal layer 141, as shown in FIG. 6C. A thickness of the second metal layer 151 ranges from 5 μm to 8 μm (including endpoint values). The metal trace includes a first metal layer 141 and a second metal layer 151 stacked within the hollowed-out region 131, the first metal layer 141 is located between the second metal layer 151 and the base substrate 11. In an example, the second metal layer may be called an electroplated layer. The materials of the second metal layer 151 and the first metal layer 141 may both be copper metal. Although the materials of the first metal layer 141 and the second metal layer 151 are the same, since the first metal layer 141 is formed by deposition and the second metal layer 151 is formed by electroplating process, the first metal layer 141 and the second metal layer 151 are two layers under a microscope. In an example, a ratio of the thickness of the second metal layer 151 to the thickness of the organic insulating layer 13 may be 1:3 to 2:3 (including endpoint values). For example, the ratio of the thickness of the second metal layer 151 to the thickness of the organic insulating layer 13 may be 1:2. Such arrangement not only facilitates the formation of the second metal layer 151 in the hollowed-out region 131, but also the organic insulating layer 13 can protect the sidewalls of the metal traces in the subsequent manufacturing process and prevent the metal traces from being eroded by water and oxygen in the subsequent manufacturing process.

The first metal thin film on the surface of the photoresist layer 13 away from the base substrate 11 is removed. This step includes: removing the first metal thin film 14 on the upper surface of the photoresist layer 13 by an etching process to obtain a wiring substrate, as shown in FIG. 6D. FIG. 6D is a schematic diagram of a wiring substrate after removing a first metal thin film on an upper surface of a photoresist layer according to an embodiment of the present disclosure. The photoresist in the photoresist pattern region constitutes the organic insulating layer 13, the metal trace 50 includes the first metal layer 141 and the second metal layer 151 in the hollowed-out region, and an opening above the metal trace 50 constitutes a first opening 132.

In the embodiment of the present disclosure, the first metal layer 141 and the second metal layer 151 are formed by the process of FIG. 6A to FIG. 6D, in which only one mask is used to form the first metal layer 141 and the second metal layer 151, and the thickness of the second metal layer 151 can reach 5 μm to 8 μm, thus realizing the thickness range required for a metal trace. Compared with the schemes of obtaining the metal trace with the required thickness range in the related technology, only one mask is used in the method for forming the first metal layer 141 and the second metal layer 151 in the present disclosure, which saves at least five masks compared with the related technology, greatly reduces the number of masks, reduces the cost and improves the competitiveness of products. In addition, the etching process is no longer used to form the first metal layer 141, which avoids the problem of sidewalls retracting inward, improves the adhesion between the metal traces and the base substrate 11, reduces the risk of the metal traces falling off, improves the die bonding yield, and improves the product performance.

In the process of FIG. 6A to FIG. 6D, the angle β between the photoresist sidewall of the photoresist pattern region and the base substrate is equal to 90°, and the angle between the sidewall of the formed first metal layer 141 and the base substrate 11 is also 90°, and the angle between the sidewall of the second metal layer 151 and the base substrate 11 is also 90°.

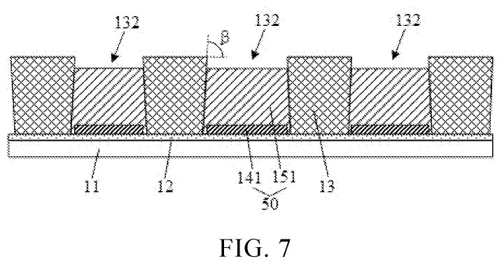

FIG. 7 is a schematic diagram of a wiring substrate after removing a first metal thin film on an upper surface of a photoresist layer according to another embodiment of the present disclosure. In one embodiment, as shown in FIG. 7, the angle β between the sidewall of the organic insulating layer 13 and the base substrate is less than 90°, that is, the cross-sectional shape of the organic insulating layer 13 is an inverted trapezoid. After the first metal layer 141 is formed by a deposition process, the width of the first metal layer 141 is less than the width of the bottom edge of the hollowed-out region 131, so that there is a gap between the sidewall of the first metal layer 141 and the photoresist. In the electroplating process, after the first metal layer 141 is electrified, an electroplated metal layer can be grown on both the side surface and the upper surface of the first metal layer 141, whereby a second metal layer 151 is formed on the side surface and the upper surface of the first metal layer 141, as shown in FIG. 7. In the electroplating process, the second metal layer 151 is grown along the sidewall of the photoresist, so that the angle between the sidewall of the second metal layer 151 and the base substrate 11 is greater than 90°.

After obtaining the metal traces, the manufacturing method of the wiring substrate may further include the following steps.

A reflective layer 17 is formed on a side of the organic insulating layer 13 and the metal traces 50 away from the base substrate 11 by using a screen printing process, and the reflective layer 17 is provided with a second opening 171, an orthographic projection of the second opening 171 on the base substrate 11 is within an orthographic projection of the hollowed-out region on the base substrate 11, and the second opening 171 exposes a portion of the surface of the metal trace 50 away from the base substrate 11, as shown in FIG. 6E. FIG. 6E is a schematic diagram of a wiring substrate after forming a reflective layer according to an embodiment of the present disclosure. The orthographic projection of the second opening 171 on the base substrate 11 is configured to be located within the orthographic projection of the hollowed-out region on the base substrate 11, whereby the reflective layer 17 is also retained on the sidewall of the first opening 132, so that the reflective layer 17 can cover the exposed surface of the organic insulating layer 13. By using the screen printing process, the reflective layer 17 and the second opening 171 can be formed at one time, which avoids masking and exposure. In an example, the reflective layer 17 may be formed by coating white ink on a side of the organic insulating layer 13 and the metal traces 50 away from the base substrate 11 and masking, exposing and developing. In an example, the material of the reflective layer 17 may be white ink.

A nickel-gold layer is grown on the surface of the metal trace 50 exposed through the second opening 171 by an ENIG process, and the nickel-gold layer may serve as an oxidization protective layer 18, as shown in FIG. 4 and FIG. 5. For example, a nickel (Ni) layer having a thickness of 3 μm to 5 μm is first produced on the surface of the metal trace 50 exposed through the second opening 171 by electroless plating; then, a gold (Au) layer is plated on the surface of the nickel layer by a displacement reaction, the thickness of the gold layer is about 0.03 μm, thereby obtaining an oxidization protective layer 18 including a nickel layer and a gold layer. An orthographic projection of the oxidization protective layer 18 on the base substrate of the wiring substrate is within a range of an orthographic projection of the second metal layer 151 on the base substrate of the wiring substrate, and the oxidization protective layer 18 is connected and in direct contact with the second metal layer 151 through the second opening 171. The material of the oxidization protective layer 18 may include nickel, for example, the material of the oxidization protective layer 18 may be a nickel-gold (NiAu) layer. The thickness of the oxidization protective layer 18 may be 4 μm to 5 μm (including endpoint values).

Compared with the schemes in the related technology for obtaining the metal trace with the required thickness range, the manufacturing method of the wiring substrate according to an embodiment of the present disclosure adopts only one mask, thus greatly reducing the number of masks, reducing the cost and improving the competitiveness of products. In addition, the etching process is no longer adopted in the process of forming the first metal layer, so that the adhesion between the first metal layer and the base substrate is improved, the risk of metal traces falling off is reduced, the die bonding yield is improved, and the product performance is improved.

The technical schemes of the embodiments of the present disclosure no longer have the problem that the surfaces of the metal traces contacting with the base substrate retract inward, but increase the contact areas between the metal traces and the base substrate, improve the adhesion between the metal traces and the base substrate, and reduce the risk of the metal traces falling off. In addition, the organic insulating layer can protect the sidewalls of the metal traces and avoid water-oxygen corrosion caused by contacting the sidewalls of the metal traces with water and oxygen.

In the description of the present specification, it should be understood that, orientation or position relationships indicated by terms “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, “clockwise”, “counterclockwise”, “axial”, “radial”, “circumferential” and the like are based on the orientation or position relationships shown in the drawings, and are only for the convenience of description of the present disclosure and simplification of the description, but are not intended to indicate or imply that the mentioned device or element must have a specific orientation, or be constructed and operated in a particular orientation, and therefore they should not be construed as limitations on the present disclosure.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In addition, terms “first” and “second” are used for descriptive purposes only and cannot be interpreted as indicating or implying relative importance or implicitly indicating a quantity of technical features indicated. Therefore, features defined by “first” or “second” may explicitly or implicitly include one or more such features. In the description of the present disclosure, a meaning of “a plurality of” is two or more than two, unless defined otherwise explicitly.

In the present disclosure, unless otherwise clearly specified and defined, terms “install”, “connect”, “couple”, “fix” and other terms should be broadly understood. For example, it may be a fixed connection, a detachable connection, or an integrated connection; or it may be a mechanical connection, an electrical connection, or a communication; or it may be a direct connection, an indirect connection through an intermediary, or an internal communication between two elements or an interaction between two elements. Those of ordinary skills in the art may understand meanings of the aforementioned terms in the present disclosure according to situations.

In the present disclosure, a first feature being “above” or “below” a second feature may include direct contact of the first feature and the second feature, or may include indirect contact of the first feature and the second feature through additional feature(s) between them, unless otherwise expressly specified and defined. Moreover, the first feature being “over”, “above” and “on” the second feature includes the first feature being directly above and obliquely above the second feature, or simply means that a level of the first feature is higher than that of the second feature. The first feature being “beneath”, “below” and “under” the second feature includes the first feature being directly below and obliquely below the second feature, or simply means that a level of the first feature is lower than that of the second feature.

Many different implementations or examples disclosed above are provided for implementing different structures of the present disclosure. In order to simplify the present disclosure, components and arrangements of specific examples are described above. Of course, they are examples only and are not intended to limit the present disclosure. In addition, in the present disclosure, reference numbers and/or reference letters may be repeated in different examples. Such repetition is for a purpose of simplification and clarity, and itself does not indicate a relationship between various implementations and/or arrangements discussed.

The above is only exemplary implementation modes of the present disclosure, but the protection scope of the present disclosure is not limited to this. Any person familiar with this technical field may easily conceive various variations or substitutions within the technical scope disclosed in the present disclosure, which should be covered within the protection scope of the present disclosure. Therefore, the protection scope of the present disclosure shall be subject to the protection scope of the claims.

1. A wiring substrate, comprising:
a base substrate;
a plurality of metal traces located on a side of the base substrate, wherein a metal trace comprises a first metal layer and a second metal layer which are stacked, the first metal layer is located between the second metal layer and the base substrate, an angle between a sidewall of the second metal layer and the base substrate is greater than or equal to 90°, and an area of a surface of the metal trace contacting with the base substrate is greater than or equal to an area of a surface of the second metal layer opposite to the first metal layer; and
an organic insulating layer disposed in the same layer as the metal traces, wherein a distance between a surface of the organic insulating layer away from the base substrate and the base substrate is greater than distances between surfaces of the metal traces away from the base substrate and the base substrate, the organic insulating layer comprises a plurality of first openings, the first openings expose a portion of the surfaces of the metal traces.

2. The wiring substrate according to claim 1, wherein,
an orthographic projection of the second metal layer on the base substrate is within a range of an orthographic projection of the first metal layer on the base substrate; or,
an orthographic projection of the first metal layer on the base substrate is within a range of an orthographic projection of the second metal layer on the base substrate, and a portion of the second metal layer is in direct contact with the base substrate in a plane parallel to the base substrate.

3. The wiring substrate according to claim 1, wherein a sidewall of the first metal layer is perpendicular to a surface of the base substrate.

4. The wiring substrate according to claim 1, further comprising a reflective layer disposed at least on a surface of a side of the organic insulating layer away from the base substrate.

5. The wiring substrate according to claim 4, wherein a material of the reflective layer is white ink.

6. The wiring substrate according to claim 4, wherein the reflective layer is further disposed on sidewalls of the first openings.

7. The wiring substrate according to claim 4, wherein a segment difference between a surface of a side of the reflective layer away from the base substrate and a surface of a side of the metal trace away from the base substrate is less than or equal to 10 μm.

8. The wiring substrate according to claim 4, wherein the reflective layer is further disposed on a surface of a side of the metal trace away from the base substrate, and the reflective layer is provided with a second opening, an orthographic projection of the second opening on the base substrate is within an orthographic projection of a first opening on the base substrate, the second opening exposes a portion of the surface of the side of the metal trace away from the base substrate.

9. The wiring substrate according to claim 8, wherein the wiring substrate further comprises an oxidization protective layer located at exposed regions of the metal traces, the oxidization protective layer is in direct contact with the metal traces, the material of the oxidization protective layer comprises nickel and gold, and the oxidization protective layer has a thickness ranging from 4 μm to 5 μm.

10. The wiring substrate according to claim 1, wherein a ratio of a thickness of the first metal layer to a thickness of the organic insulating layer is less than or equal to 1/30.

11. A manufacturing method for a wiring substrate, comprising:
forming a photoresist layer on a side of a base substrate, patterning the photoresist layer to form a photoresist pattern region and a hollowed-out region, wherein the hollowed-out region has no photoresist, and an angle between a photoresist sidewall of the photoresist pattern region and the base substrate is less than or equal to 90°;
depositing a first metal thin film on a side of the base substrate facing the photoresist layer, wherein a ratio of a thickness of the first metal thin film to a thickness of the photoresist layer is less than or equal to 1/30, and the first metal thin film located in the hollowed-out region constitutes a first metal layer;
forming a second metal layer on at least a surface of the first metal layer facing away from the base substrate by an electroplating process, wherein a distance between a surface of the photoresist layer away from the base substrate and the base substrate is greater than a distance between a surface of the second metal layer away from the base substrate and the base substrate; and
removing the first metal thin film on the surface of the photoresist layer away from the base substrate to obtain the wiring substrate, wherein the photoresist in the photoresist pattern region constitutes an organic insulating layer, and a metal trace comprises the first metal layer and the second metal layer in the hollowed-out region.

12. The method according to claim 11, further comprising:
forming a reflective layer on a side of the organic insulating layer and the metal traces away from the base substrate by a screen printing process, wherein the reflective layer is provided with a second opening, an orthographic projection of the second opening on the base substrate is within an orthographic projection of the hollowed-out region on the base substrate, and the second opening exposes a portion of a surface of the side of the metal trace away from the base substrate.

13. The method according to claim 12, further comprising: performing electroless nickel immersion gold on the exposed surfaces of the metal traces.

14. A light-emitting panel, comprising the wiring substrate of claim 1, and further comprising a plurality of light emitting diode chips, wherein the plurality of light emitting diode chips are correspondingly connected with the metal traces.

15. A display device, comprising the light-emitting panel according to claim 14.
